(19) United States
(12) Patent Application Publication
(10) Pub. No.: US 2013/0221974 A1
(43) Pub. Date: Aug. 29, 2013

(54) TIME DOMAIN REFLECTOMETRY SYSTEM AND METHOD

(71) Applicant: GM Global Technology Operations LLC, (US)

(72) Inventors: TIMOTHY D. JULSON, ROCHESTER HILLS, MI (US); GARY W. TARASKI, OXFORD, MI (US); KIMBERLEY R. WILL, MACOMB TOWNSHIP, MI (US); KHARA D. PRATT, REDFORD, MI (US)

(73) Assignee: GM GLOBAL TECHNOLOGY OPERATIONS LLC, Detroit, MI (US)

(21) Appl. No.: 13/767,384

(22) Filed: Feb. 14, 2013

Related U.S. Application Data
(60) Provisional application No. 61/605,037, filed on Feb. 29, 2012.

(51) Int. Cl. G01R 31/28

(52) U.S. Cl. CPC G01R 31/2841
USPC 324/503; 324/537

(57) ABSTRACT

Methods and systems are provided for determining conductor abnormalities using time reflectometry. The system includes a database configured to store data regarding an impedance of at least one element of an electric circuit. The system also includes a pulse generator for generating a signal pulse. A transmitter is in communication with the pulse generator for transmitting the signal pulse into the electric circuit. The system further includes a receiver for receiving a reflection of the signal pulse from the electric circuit. A processor in communication with the receiver and the database is configured to determine an abnormal condition based on the received reflection of the signal pulse and the data stored in the database.

### CROSS REFERENCE TO RELATED APPLICATIONS

This application claims the benefit of U.S. Provisional Application No. 61/605,037, filed Feb. 29, 2012, which is hereby incorporated by reference.

### TECHNICAL FIELD

The technical field generally relates to time domain reflectometry, and more particularly relates to time domain reflectometry systems and methods for wiring in a vehicle.

### BACKGROUND

Vehicles, such as automobiles, increasingly utilize electrical circuitry for critical systems. Accordingly, the quality and reliability of electrical wiring and other electrical conductors in the vehicle are becoming an important concern. Suppliers of wiring harnesses often perform a continuity check on each wiring harness at the end of the manufacturing process. While such continuity checks assure the presence of the circuit in the right cavity of the connector, they do not provide any indication of the state of health of the wires and conductors of the circuits. Moreover, such testing often misses circuits that will soon fail, such as bad wire crimps.

Accordingly, it is desirable to develop more robust methods of sensing and locating electrical faults and abnormalities in wiring harnesses and other electrical circuits. Furthermore, other desirable features and characteristics of the present disclosure will become apparent from the subsequent detailed description and the appended claims, taken in conjunction with the accompanying drawings and the foregoing technical field and background.

### SUMMARY

A time domain reflectometry (“TDR”) system is provided. In one embodiment, the TDR system includes a database configured to store data regarding an impedance of at least one element of an electric circuit. The TDR system also includes a pulse generator for generating a signal pulse. A transmitter is in communication with the pulse generator for transmitting the signal pulse into the electric circuit. The TDR system further includes a receiver for receiving a reflection of the signal pulse from the electric circuit. A processor in communication with the receiver and the database is configured to determine an abnormal condition based on the received reflection of the signal pulse and the data stored in the database.

A method is provided for sensing abnormalities in an electrical circuit. In one embodiment, the method includes storing data regarding impedances of at least one element of an electric circuit in a database. The method also includes generating a signal pulse. The signal pulse is transmitted into the electric circuit. The method further includes receiving a reflection of the signal pulse from the electric circuit. The method also includes determining an abnormal condition based on the received reflection of the signal pulse and the data stored in the database.

A vehicle is also provided. In one embodiment, the vehicle includes a plurality of electric circuits and an on-board TDR system. The TDR system includes a database configured to store data regarding impedances of elements of the plurality of electric circuits. The TDR system further includes a pulse generator for generating a signal pulse. A transmitter is in communication with the pulse generator for transmitting the signal pulse into the electric circuit. The TDR system also includes a receiver for receiving a reflection of the signal pulse from the electric circuit. A processor in communication with the receiver and the database is configured to determine an abnormal condition based on the received reflection of the signal pulse and the data stored in the database.

### DESCRIPTION OF THE DRAWINGS

The exemplary embodiments will hereinafter be described in conjunction with the following drawing figures, wherein like numerals denote like elements, and wherein:

FIG. 1 is an electrical schematic of a time domain reflectometry system implemented in a vehicle in accordance with an embodiment;

FIG. 2 is a chart representing data organized in a database in accordance with an embodiment;

FIG. 3 is a graph showing a pulse reflection trace of a normal circuit in accordance with an embodiment;

FIG. 4 is a graph showing a pulse reflection trace of an open circuit in accordance with an embodiment;

FIG. 5 is a graph showing a pulse reflection trace of a short circuit in accordance with an embodiment; and

FIG. 6 is a graph showing a pulse reflection trace of an abnormal circuit due to a non-optimal wire crimp in accordance with an embodiment.

### DETAILED DESCRIPTION

The following detailed description is merely exemplary in nature and is not intended to limit the application and uses. Furthermore, there is no intention to be bound by any expressed or implied theory presented in the preceding technical field, background, brief summary or the following detailed description.

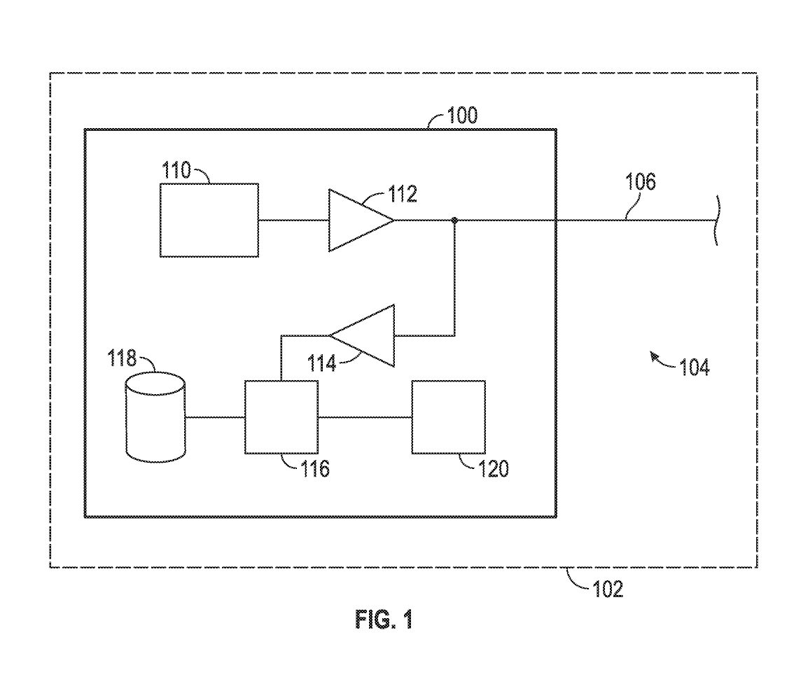

Referring to the figures, wherein like numerals indicate like parts throughout the several views, a time domain reflectometry (“TDR”) system 100 is shown herein. In the exemplary embodiment, as shown in FIG. 1, the TDR system 100 may be utilized with a vehicle 102. More specifically, the vehicle 102 of the exemplary embodiment is an automobile. However, the TDR system 100 may be utilized with other vehicles, e.g., aircraft, or non-vehicle applications.

The vehicle 102 of the exemplary embodiment includes a plurality of electric circuits 104; however, only one circuit 104 is illustrated in FIG. 1. The TDR system 100 of one embodiment may be normally carried on-board the vehicle 102. However, in other embodiments, the TDR system 100 may be connected and disconnected from the vehicle 102 and its circuits 104.

Each circuit 104 includes at least one conductor 106. In normal operation, the conductor 106 may electrically connect a load (not shown) to a power source (not shown) as is well known to those skilled in the art. The conductor 106 may include various elements (not numbered). These elements include, but are certainly not limited to, wires, terminals, bus bar, conductive pathways on a circuit board, and solder joints. The terminals may include, but are not limited to, sockets, pins, and wire crimps. The terminals may be housed in or supported by a non-conductive connector as part of a wire harness or wire assembly, as is appreciated by those skilled in the art.

The TDR system 100 includes a pulse generator 110 for generating at least one signal pulse. The TDR system 100 further includes a transmitter 112 in communication with the pulse generator 110. The transmitter 112 receives the signal pulse from the pulse generator 110 and transmits the signal pulse into the electric circuit 104. More specifically, the transmitter is electrically connectable to one end (not numbered) of the conductor 106. The pulse generator 110 and the transmitter 112 may be integrated into a single unit, as is appreciated by those skilled in the art.

The TDR system 100 further includes a receiver 114. As the signal pulse propagates through the conductor 106, reflections may occur due to impedances in the circuit 104. These impedances may be caused by the various elements of the conductor 106. These reflections of the signal pulse are received by the receiver 114. The various reflections received by the receiver 114 may be utilized to identify normal and/or abnormal conditions on the conductor 106 and the circuit 104.

More specifically, in the exemplary embodiment, a processor 116 in communication with the receiver 114 to analyze the received reflected signal and determine normal and/or abnormal conditions of the conductor 106. The processor 116 may be a microprocessor, microcontroller, application specific integrated circuit (“ASIC”) or other computational device capable of performing calculations and executing instructions.

The pulse width (i.e., the duration) and the rise-time of the signal pulse generated by the pulse generator 110 may be dependent on the specific elements of the conductor 106 that are being monitored. More specifically, a length and a nominal velocity of propagation (“NVP”) of the element that is being scrutinized may dictate the pulse width and/or the rise-time of the signal pulse. The NVP is a percentage of the speed of light (c). For example, a wire crimp may have a length of 3.3 mm and an NVP of 66%. The pulse rise time=1/f and the length of the element (L)=NVP/2f. As such, the rise time for the signal pulse is 30 picoseconds.

In order to determine if an abnormal condition is present on the circuit 104, the parameters of a normal (i.e., “good”) conductor 106 must be known. Therefore, the TDR system 100 further includes a database 118 configured to store data related to a plurality of circuits 104. More specifically, the database 118 of the exemplary embodiment includes impedance data for a plurality of elements of the circuits 104. For instance, the different impedances for different lengths, types, and materials of wire may each be included in the database 118. The database 118 may also include, but is not limited to, impedances for pins, sockets, and other terminals.

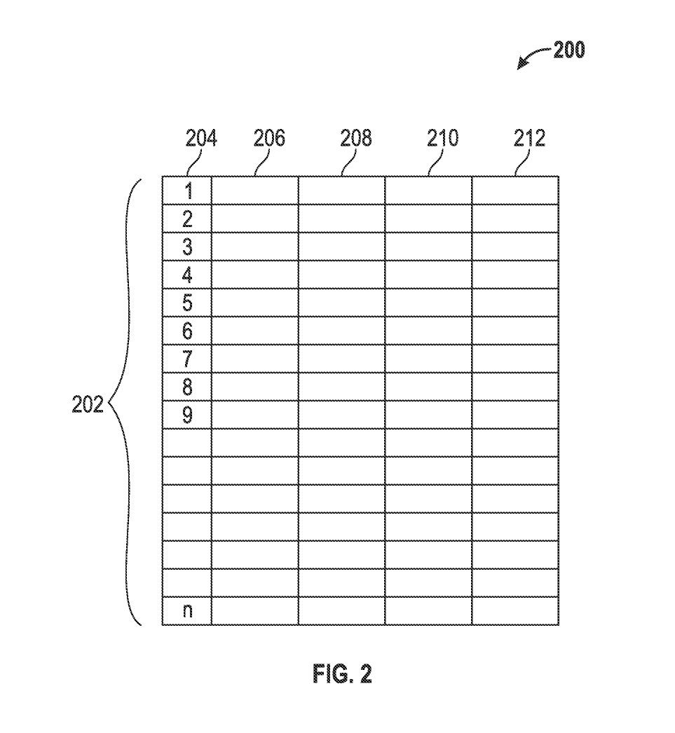

FIG. 2 shows a chart 200 representing data organized in an exemplary database 118. With continuing reference to FIG. 1, the rows 202 of the chart each correspond to a unique circuit 104, a portion of a circuit 104, a conductor 106, and/or a portion of a conductor 106 of the vehicle 102. The first column 204 includes circuit identifiers corresponding to each unique circuit 104, conductor 106, or portion thereof. The second column 206 includes an acceptable upper impedance limit for a wire crimp of a terminal in the circuit 104 and/or conductor 106 identified in the first column 204. The third column 208 includes an acceptable lower impedance limit for the wire crimp of a terminal. In this exemplary embodiment, a normal impedance for the wire crimp falls between these limits, while an abnormal impedance for the wire crimp lies outside of these limits.

The fourth column 210 includes an upper impedance limit for a wire section of the circuit 104 identified in the corresponding row of the first column 204. The fifth column 212 includes a lower impedance limit for the wire section. In this exemplary embodiment, a normal impedance for the wire segment lies between these limits, while an abnormal impedance for the wire section falls outside of these limits. More specifically, a measured impedance higher than the upper impedance limit of the fourth column 212 indicates an open circuit while a measured impedance lower than the lower impedance limit of the fifth column 214 indicates a short circuit.

Of course, the configuration of the database 118 as shown in FIG. 2 is only exemplary in nature. Other configurations, data, classifications, etc. may be utilized in other embodiments.

In one embodiment, the data stored in the database 118 is based on known standards and does not change over time. However, in other embodiments the processor 116 may be configured to calculate normal and/or abnormal impedances and/or limits over time for any combination of the wires, terminals, splices, or other electrical components involved in the conductor 106 based on measurements made by the processor 116.

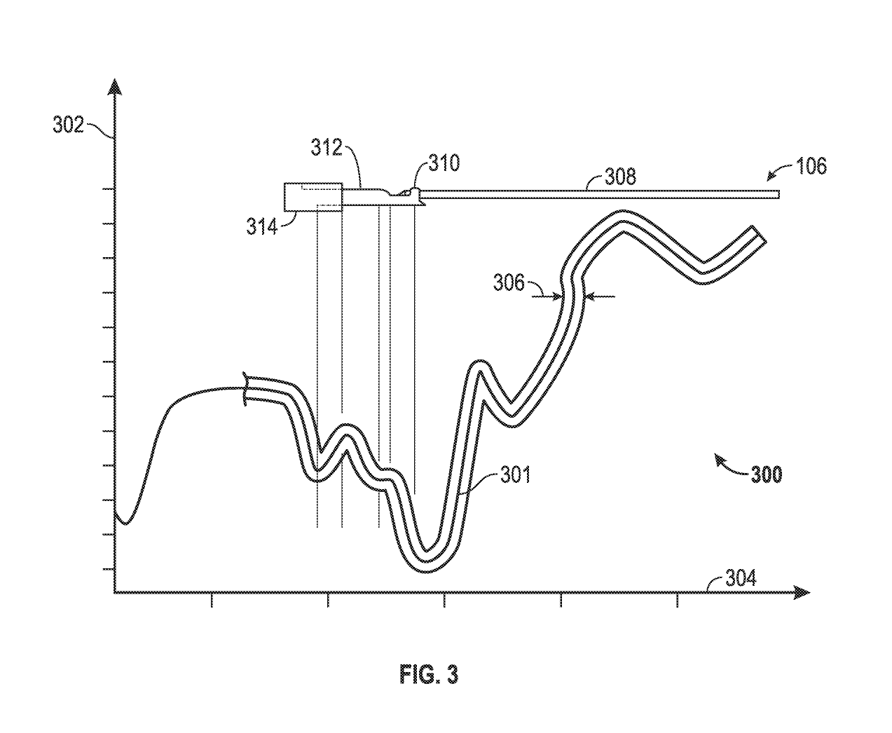

The parameters of an exemplary normal conductor 106 are shown in a graph 300 shown in FIG. 3. The graph 300 shows an exemplary normal trace 301 over the length of one conductor 106. A vertical axis 302 of the graph 300 corresponds to impedances and a horizontal axis 304 corresponds to time of the reflected pulse. FIG. 3 also illustrates a range 306 of acceptable impedances at different times corresponding to upper and lower acceptable impedance limits. A wire 308, wire crimp 310, terminal socket 312, and non-conductive connector 314 housing part of the terminal socket 312 are also shown in FIG. 3. Each of these elements 308, 310, 312, 314 is aligned with the normal trace 301 to show the change in impedance over time of the reflected pulse signal.

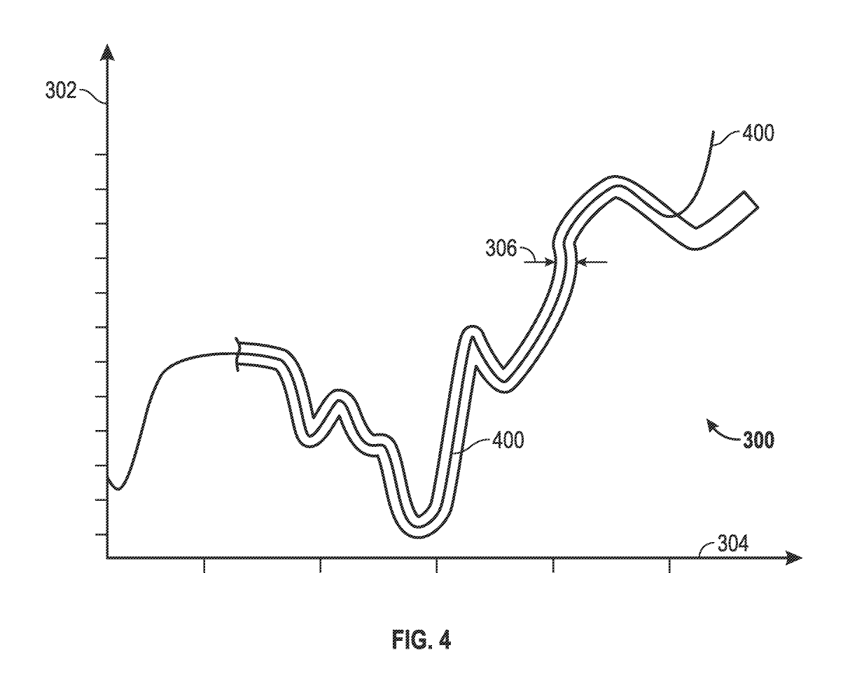

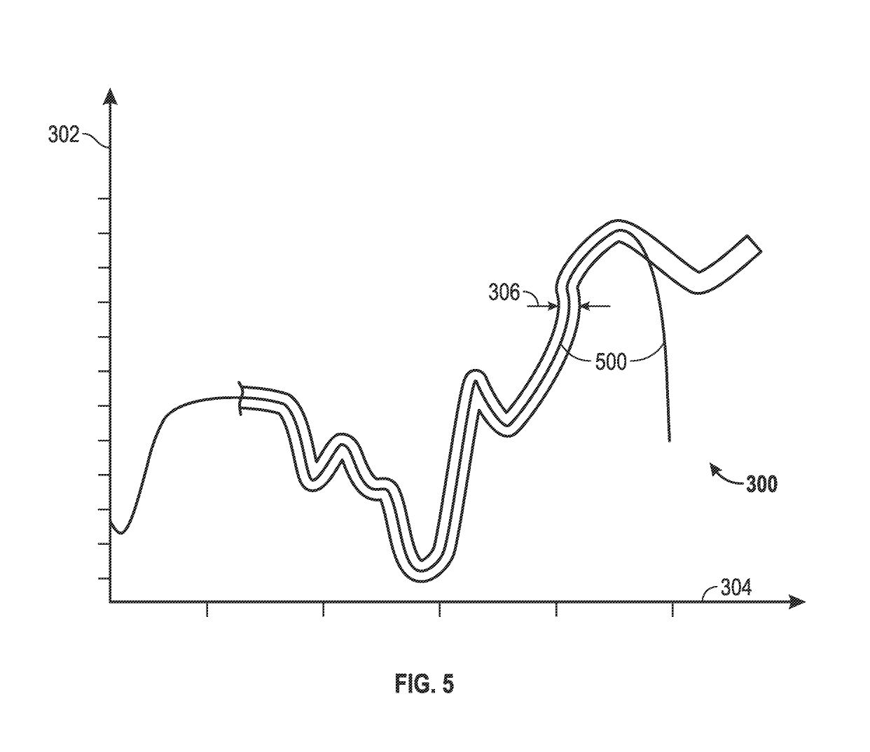

A trace 400 on the graph 300 in FIG. 4 illustrates an open circuit. Specifically, the trace 400 extends upward (i.e., towards an infinite impedance) out of the range 306 of acceptable impedances. A trace 500 on the graph 300 in FIG. 5 illustrates a short circuit. Specifically, the trace 500 extends downward (i.e., towards zero impedance) out of the range 306 of acceptable impedances.

While short and open circuits may be easily recognizable using analysis of the received reflections, as shown in FIGS. 4 and 5, other abnormalities in the circuit 104 present more subtle changes in impedance. For instance, a non-optimal wire crimp between a wire and a terminal may allow the circuit 104 to function normally for a time. However, the electrical connectivity of the wire crimp may eventually break down. This may lead to failure of the load being powered by the conductor 106.

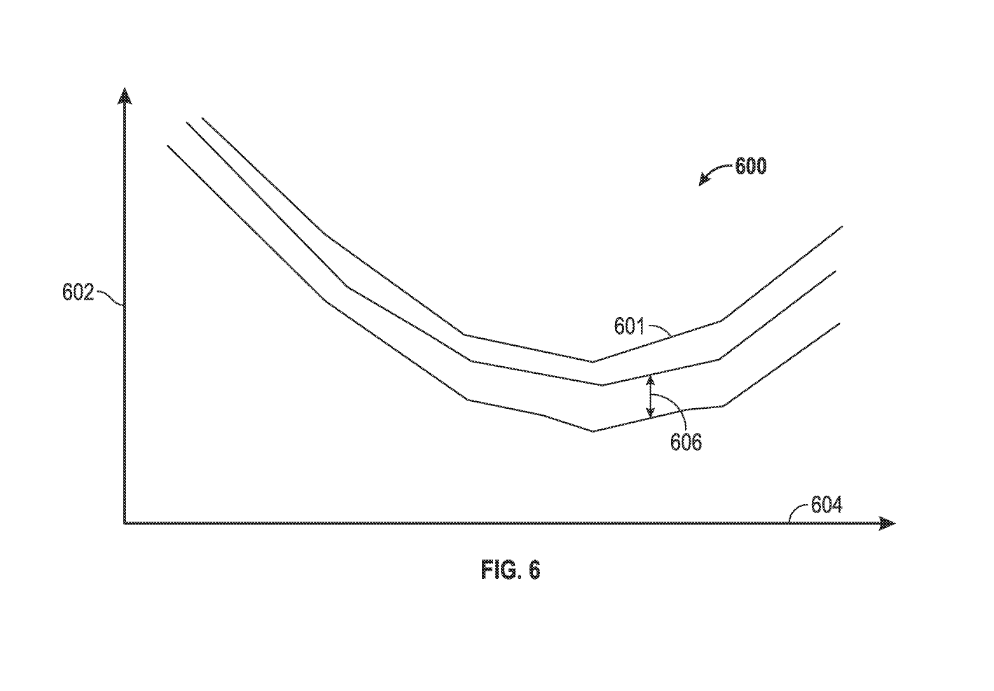

Referring now to FIG. 6, a graph 600 shows an exemplary abnormal trace 601 at non-optimal wire crimp between a wire and a terminal of one circuit 104. A vertical axis 602 of the graph 600 corresponds to impedances and a horizontal axis 604 corresponds to time of the reflected pulse. FIG. 6 also illustrates a range 606 of acceptable impedances at different times corresponding to upper and lower acceptable impedance limits.

Referring again to FIG. 1, the TDR system 100 includes an annunciator 120 in communication with the processor 116 for conveying information to a user. Particularly, the annunciator 120 may alert the user that an abnormal condition exists one or more of the circuits 104 and/or conductors 106. The annunciator 120 may include a display (not separately shown), a speaker (not separately shown), or other suitable device as appreciated by those skilled in the art.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof

What is claimed is:

1. A time domain reflectometry (“TDR”) system, comprising:
a database configured to store data regarding an impedance of at least one element of an electric circuit;
a pulse generator for generating a signal pulse;
a transmitter in communication with said pulse generator for transmitting the signal pulse into the electric circuit;
a receiver for receiving a reflection of the signal pulse from the electric circuit; and
a processor in communication with said receiver and said database and configured to determine an abnormal condition based on the received reflection of the signal pulse and the data stored in said database.

2. A TDR system as set forth in claim 1 wherein at least one of the elements of the electric circuit is a wire crimp.

3. A TDR system as set forth in claim 2 wherein the data of said database includes a normal impedance range for the wire crimp.

4. A TDR system as set forth in claim 2 wherein the wire crimp is part of a terminal.

5. A TDR system as set forth in claim 4 wherein at least part of the terminal is disposed in a non-conductive connector.

6. A TDR system as set forth in claim 4 wherein the terminal is further defined as a pin.

7. A TDR system as set forth in claim 4 where the terminal is further defined as a socket.

8. A TDR system as set forth in claim 1 wherein at least one of the elements of the electric circuit is a wire.

9. A TDR system as set forth in claim 1 wherein said electric circuit is further defined as a plurality of electric circuits.

10. A vehicle, comprising:
a plurality of electric circuits; and
an on-board TDR system including
a database configured to store data regarding impedances of elements of the plurality of electric circuits,
a pulse generator for generating a signal pulse,
a transmitter in communication with said pulse generator for transmitting the signal pulse into the electric circuit,
a receiver for receiving a reflection of the signal pulse from the electric circuit, and
a processor in communication with said receiver and said database and configured to determine an abnormal condition based on the received reflection of the signal pulse and the data stored in said database.

11. A vehicle as set forth in claim 10 wherein at least one of the elements of the electric circuit is a wire crimp.

12. A vehicle as set forth in claim 11 wherein the data of said database includes a normal impedance range for the wire crimp.

13. A vehicle as set forth in claim 11 wherein the wire crimp is part of a terminal.

14. A vehicle as set forth in claim 13 wherein at least part of the terminal is disposed in a non-conductive connector.

15. A vehicle as set forth in claim 10 wherein at least one of the elements of the electric circuit is a wire.

16. A method of sensing abnormalities in an electric circuit, comprising:
storing data regarding impedances of at least one element of an electric circuit in a database;
generating a signal pulse;
transmitting the signal pulse into the electric circuit;
receiving a reflection of the signal pulse from the electric circuit; and
determining an abnormal condition based on the received reflection of the signal pulse and the data stored in the database.

17. A method as set forth in claim 16 wherein the at least one element is a wire crimp and wherein storing data regarding impedances comprises storing a normal impedance range for the wire crimp.

18. A method as set forth in claim 16 wherein determining an abnormal condition comprises comparing the reflection of the signal pulse to the normal impedance range.

19. A method as set forth in claim 16 further comprising alerting a user to the abnormal condition in response to an abnormal condition being determined.
